(19) United States
(12) Patent Application Publication
(10) Pub. No.: US 2012/0216853 A1
(43) Pub. Date: Aug. 30, 2012

(54) INTEGRATED SOLAR ENERGY SYSTEM

(76) Inventor: John ROUNTREE, Westport, CT (US)

(21) Appl. No.: 13/035,378

(22) Filed: Feb. 25, 2011

(51) Int. Cl. H01L 31/058; F24J 2/30; F24J 2/04

(52) U.S. Cl. 136/248; 126/634; 126/678; 126/640

(57) ABSTRACT

The system is an integrated solar energy system which provides solar generated electricity by photovoltaic panels, provides solar generated hot water by solar collector thermal panels and which has a heat recovery ventilation system which can provide heated or cooled air. The system further provides a durable long lasting roof membrane.

### BACKGROUND OF THE DISCLOSURE

1. Field of the Disclosure

The present disclosure relates to an integrated solar energy system which includes photovoltaic cells which provide solar generated electricity, solar thermal collector panels which provide solar generated hot water and a heat recovery ventilation system which can through a cooling effect, improve the performance of the photovoltaic modules year-round and provide useful heated air to a building during the heating season.

2. Description of the Prior Art

The utility and desirability of solar generated energy have been well-established on economic, political and environmental grounds. However, in spite of the nearly universal popular support for such energy, solar generated energy continues to provide only a very small portion of the energy requirements, either nationally or internationally.

The capture of the solar energy and the subsequent conversion into useful energy can take many forms. Firstly, photovoltaic cells can be used to generate electricity which can be used either in a local application such as a building or can be provided to an electrical grid for remote distributed generation. Secondly, solar energy can be used to heat water which can be used within the vicinity of the capture of the solar energy, typically within an associated structure or building. Thirdly, solar energy can be used to heat or cool air which, again, is typically used with the vicinity of the capture of the solar energy.

While attempts have been made to increase the energy output of a solar installation by combining a photovoltaic device and a fluid transport region as shown in U.S. Patent Application Publication 2010/0147347 entitled “Method and Structure for Hybrid Thermal Solar Panel”, published on Jun. 17, 2010 on behalf of Dyreby, further improvements are sought in the energy output of solar installations.

Other prior art includes U.S. Pat. No. 7,858,874 entitled “Continuous Circuit Overlay Solar Shingles”, issued on Dec. 28, 2010 to Ruskin et al.; U.S. Pat. No. 7,714,224 entitled “Photovoltaic Power Generation Module and Photovoltaic Power Generation System Employing Same”, issued on May 11, 2010 to Abe et al.; U.S. Patent Application Publication 2010/0325976 entitled “Solar Shingle System”, published on Dec. 30, 2010 on behalf of Degenfelder et al.; U.S. Patent Application Publication 2010/0275902 entitled “Photovoltaic and Thermal Energy System”, published on Nov. 4, 2010 on behalf of Fabel; U.S. Patent Application Publication 2010/0275532 entitled “Solar Roof Tile with Solar and Photovoltaic Production of Hot Water and Electrical Energy”, published on Nov. 4, 2010 on behalf of De Nardis; U.S. Patent Publication 2009/0223550 entitled “Roof Tile or Tiled Solar Thermal Collector”, published on Sep. 10, 2009 on behalf of Curtin et al; and WO 2008/073905 A2 entitled “Solar Roof Tiles and Modules with Heat Exchange” published on Jun. 19, 2008 on behalf of Corrales et al.

### SUMMARY AND OBJECTS OF THE DISCLOSURE

It is therefore an object of the present disclosure to provide solar energy equipment with a high energy output.

It is therefore a further object of the present disclosure to provide solar energy equipment which is reliable and requires minimal maintenance.

It is therefore a still further object of the present disclosure to provide solar energy equipment which is readily and easily installed on a wide range of architectural structures.

These and other advantages are obtained by providing a building-integrated solar system which provides solar generated electricity, provides solar generated hot water and which has a heat recovery ventilation system which can provide solar heated air in the winter as well as cooled air to the photovoltaic panels in the summer. The system further provides a durable long lasting roof membrane.

Further, the system typically integrates these four functions into one product while providing an architecturally pleasing, flush mounted appearance. It is expected that the combination and synergy of multiple solar strategies will typically increase the overall efficiency of the system and consequently, the economic investment return.

The system will typically include three separate renewable energy systems—solar photovoltaic panels, solar domestic hot water heating and a solar powered heat recovery system. The energy systems are typically integrated into a seamless, continuous roofing structure and will operate independently, yet synergistically.

The system will typically be provided in the form of a combination of photovoltaic panels and solar domestic hot water heating panels, and will typically be designed to be modular and adaptable to a variety of roof shapes. The system will typically utilize commercial skylight and curtain wall technology. The panels are typically mounted to a concealed aluminum frame. Further, the system will typically have a continuous air space below the panels to allow air circulation. The panels typically will be flashed into a roof that is built-up around the perimeter of the system so that the roof and panels are flush with each other. Alternatively, the entire roof surface can be designed using the present system thereby creating an aesthetic appearance.

### BRIEF DESCRIPTION OF THE DRAWINGS

Further objects and advantages of the invention will become apparent from the following description and from the accompanying drawings, wherein:

FIG. 1 is a plan view of the exterior of the system of a typical embodiment of the present disclosure.

FIG. 2 is an elevation view of a house, including the system of the present disclosure.

FIG. 3 is a cross-sectional view along plane 3-3 of FIG. 2.

FIG. 4 is an enlarged plan view of the exterior at the location of the thermal collectors of the present disclosure.

FIG. 5 is a plan view of an interior of the thermal collectors of the present disclosure.

FIG. 6 is a cross-sectional view showing typical rafter detail at a perimeter of the array of the system of the present disclosure.

FIG. 7 is a cross-sectional view showing typical purlin detail at a top of the array of the system of the present disclosure.

FIG. 8 is a cross-sectional view showing typical purlin detail at a base of the array of the system of the present disclosure.

FIG. 9 is a cross-sectional view showing typical purlin detail in the system of the present disclosure.

FIG. 10 is a cross-sectional view showing typical purlin detail at a photovoltaic/hot water panel in the system of the present disclosure.

FIG. 11 is a cross-sectional view showing typical purlin detail at two hot water panels in the system of the present disclosure.

FIG. 12 is a cross-sectional view showing typical rafter detail in the system of the present disclosure.

FIG. 13 is a cross-sectional view showing typical rafter detail at a photovoltaic/hot water panel in the system of the present disclosure.

FIG. 14 is a typical rafter detail at two hot water panels in the system of the present disclosure.

FIG. 15 is a plan view, partially in phantom, of the exterior of the system of a typical embodiment of the present disclosure.

### DETAILED DESCRIPTION OF THE PREFERRED EMBODIMENT

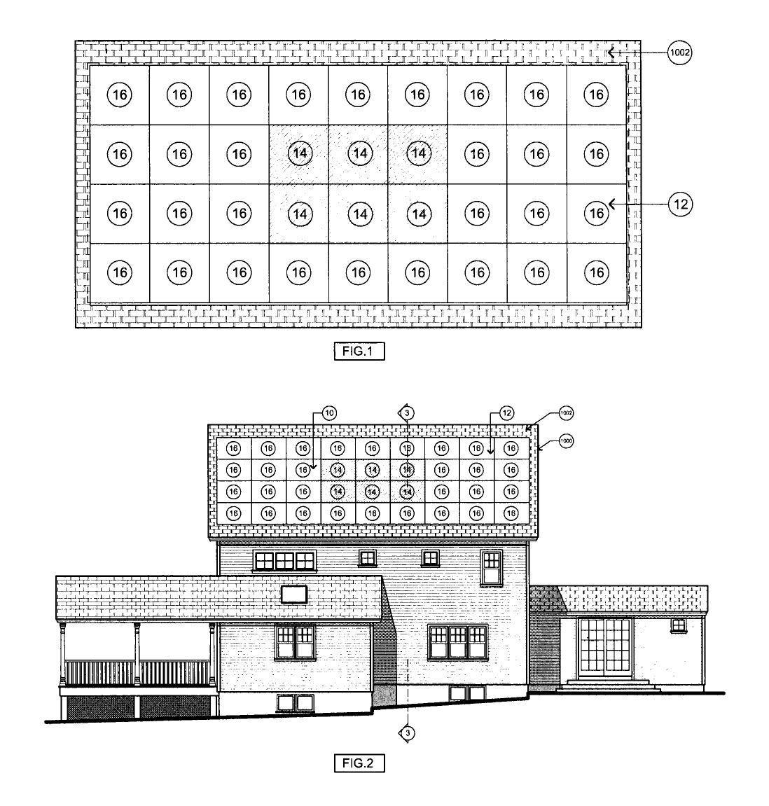

Referring now to the drawings in detail wherein like numerals indicate like elements throughout the several views, one sees that FIG. 1 is an elevation view of an exterior of the system 10 of the present disclosure while FIG. 2 is an elevation view of the system 10 mounted on a house 1000 which can, of course, be virtually any architectural structure, and is not limited thereby. Typically, the system 10 is mounted on roof 1002 of house 1000. Solar array 12 is shown as a nine by four array or matrix formed from centrally located solar thermal collector panels 14 (adjacent to each other) surrounded by photovoltaic panels 16 (adjacent to each other) around the perimeter. Of course, other sizes of arrays could be used for different applications, with different numbers of panels, depending upon the underlying architectural constraints and the amount of energy required from the system. Solar thermal collector panels 14 are configured for solar domestic hot water, while photovoltaic panels 16 are configured to generate electricity.

The solar thermal collector panels 14 and the photovoltaic panels 16 are typically of a size of four feet by four feet (but not limited thereto) and configured as a modular grid, mounted on a suitable framing material 18, such as, but not limited to, aluminum, comprised of horizontal purlins 20 and rafters 21 following the downward diagonal slope of the roof 1002, whereby the purlins 20 are generally perpendicular to the rafters 21. The panels 14, 16 are secured to the frame 18 using structural silicone. Preferably, there are few, if any, exposed framing material or glazing pressure plates on the finished surface. Preferably, the glass and the silicone joints should be the only significant components of substantial visibility. The system 10 is typically designed and intended to be flush with adjacent surfaces of roof 1002 and unobtrusive to the architectural design of the house 1000, building, or other structure.

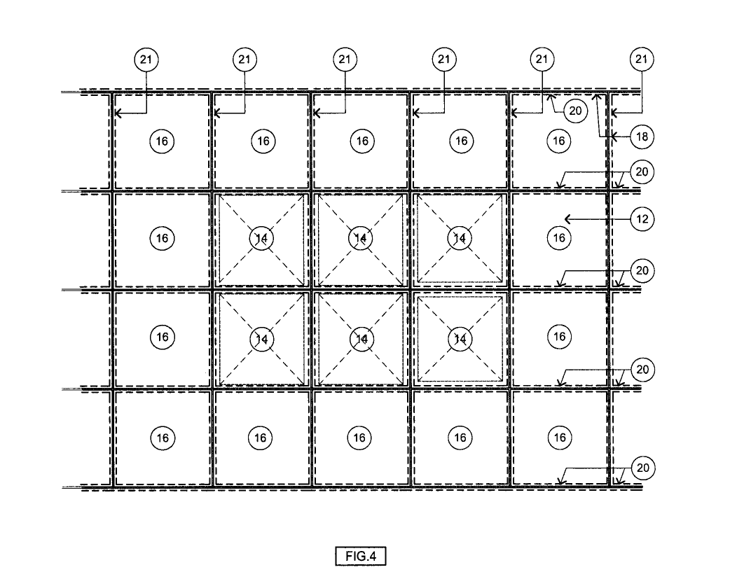

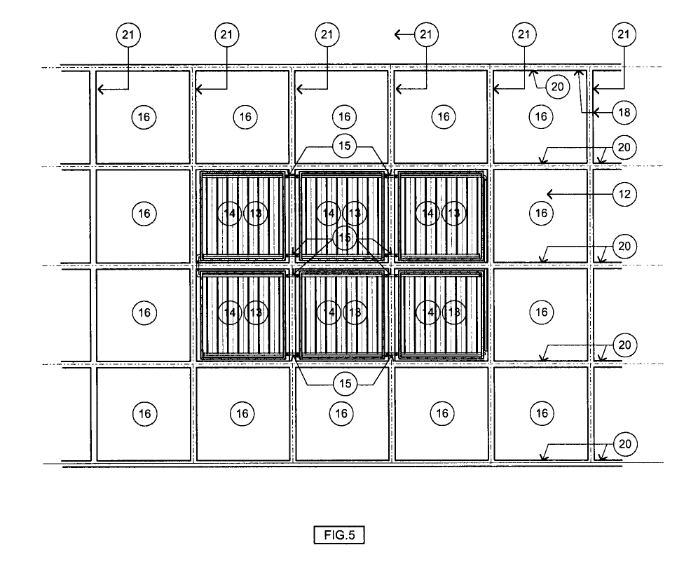

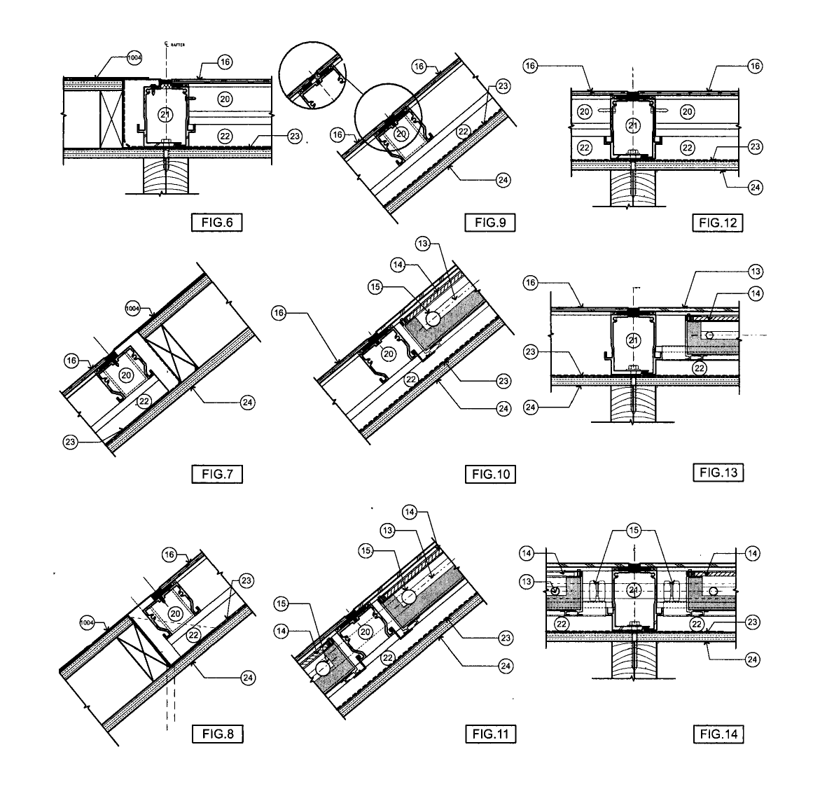

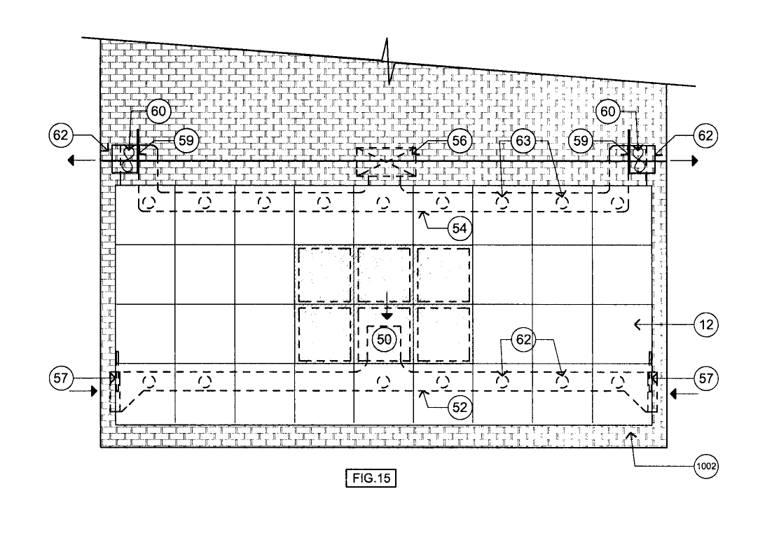

As best seen in FIGS. 6-14, a continuous air strip 22 (typically, but not limited to, a gap with thickness of one and one half inches) forms a channel below panels 14, 16 in order to allow air circulation. Continuous air strip 22 typically has a lower rubber liner 23, which may be made from, but not limited to, ethylene propylene diene Monomer (M-class) (EPDM) rubber with a lower plywood layer 24. As described hereinafter, continuous air strip 22 is used as a conduit in the heat-recovery system. In some applications, the perimetric photovoltaic panels 16 are flashed into shingles 1004 of a roof 1002 that is built-up around the perimeter of the system 10 so that the roof 1002 and perimetric photovoltaic panels 16 are flush with each other. Alternately, the entire roof 1002 can be designed with the system 10, creating an aesthetic, even modern, appearance. It is envisioned that there will be preferably no exposed metal on the surface of roof 1002, only glass and caulk joints.

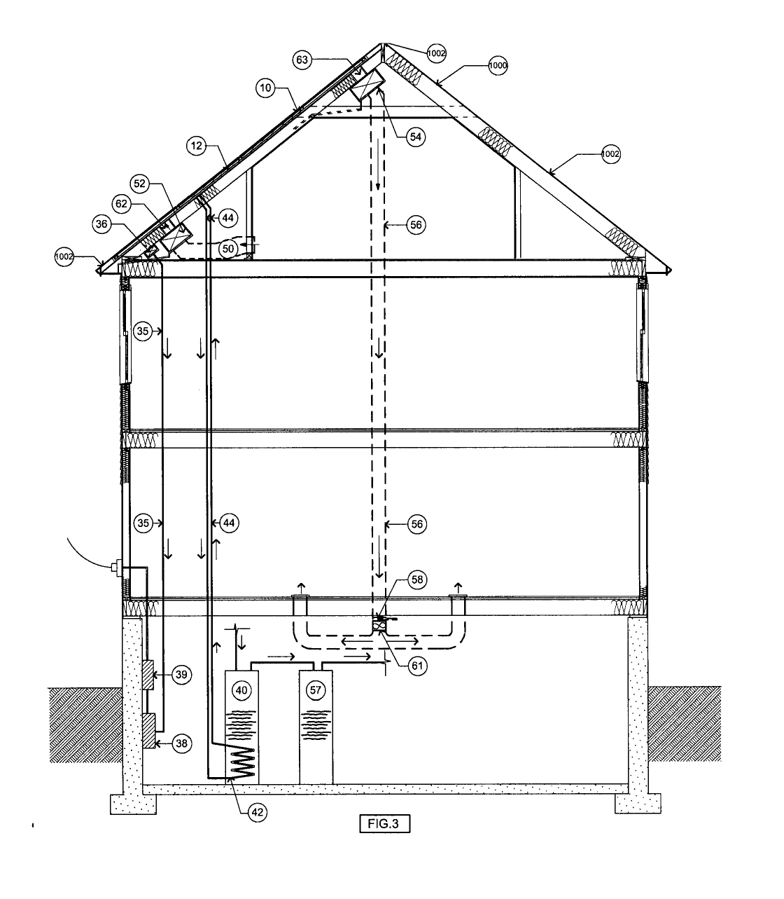

The photovoltaic panels 16 are made of conventional photovoltaic material which will generate electricity in response to sunlight. More particularly, the photovoltaic panels 16 are typically 195 watt glass-on-glass frameless laminates which contain a rear junction box and are wired together in series in order to achieve increased voltage levels. The conductors from the individual strings of photovoltaic panels 16 are combined and taken through a single pitch pocket penetrating the roof 1002 to a combiner box 36 below the roof 1002 (see FIG. 3). A single DC conduit 35 runs from the combiner box 36 to an inverter 38 located near the main service panel 39, typically found in the basement. The function of the inverter 38 is to convert the DC output of the photovoltaic panels 16 into utility grade AC power. It is envisioned that, typically, the system 10 would not replace electrical service from the utility, but rather supplement it, offsetting a portion of electricity purchased from the grid, thereby reducing the utility expenses. However, it is envisioned that the inverter 38 may be configured to supply electricity to the grid whenever the system 10 produces more electricity than is required by the house 1000 or other associated structure and that the homeowner would receive a credit for this surplus electricity.

The solar thermal collector panels 14 are typically designed to fit and operate within system 10 and typically include an exterior glass surface. The solar thermal collector panels 14 use flat-plate collector technology, typically using a copper pipe welded to a copper plate 13 within an insulated collector box. The solar thermal collector panels 14 further include an anti-freeze fluid that runs through the thermal collector panels 14 and through copper tubing 15 between adjacent solar thermal collector panels 14 (or similar pipes or conduits, see FIGS. 5, 10, 11, 13 and 14) so as to be heated by successive solar thermal collector panels 14. The heated anti-freeze fluid is thereafter pumped or otherwise moved to internal heat exchanger 42 via piping system 44 so that the heat generated by solar energy may be transferred to water storage tank 40. The internal heat exchanger 42 exchanges heat from the anti-freeze fluid to the water without contact or mixing between the two fluids. Heated water from the water storage tank 40 can be used to directly feed the hot water demands of the house 1000 or supply pre-heated water to a conventional hot water heater 57 or an on-demand water heater.

The heat recovery system has the functions of removing unwanted thermal energy from beneath the photovoltaic panels 16 during the cooling season, thereby increasing the conversion efficiency of photovoltaic panels 16 and further of providing preheated air to the house 1000 during the heating season thereby reducing the heating load and the use of conventional heating fuels. The air movement and mode of operation is controlled automatically by a “smart” microprocessor thermostat and a designed system of ducts, automatic dampers 57, 58, 59 and fans 60, 61. As shown in FIG. 3 and FIG. 15, these ducts include the return air duct 50, which provides air to the supply duct 52 and then through branch ducts 62 to the previously described channel formed by continuous air strip 22; then to the exhaust duct 54, via channel 63. From the exhaust duct 54 the air is directed to either the outside 62 by fans 60, in the cooling season or to a return duct 56 and taken to the basement by a fan 61 and then to the house 100, in the heating season. The automatic dampers 57 and 59 are typically closed in the heating season and open in the cooling season.

The exhaust fans 60 typically operate in the cooling season when the dampers 57 and 59 are open and the return fan 61 operates during the heating season when dampers 57 and 59 are closed.

Typically, the return air duct 50 and the continuous supply duct 52 and the branch ducts 62 are placed near a lower portion of the roof 1002. Typically the continuous exhaust duct 54 and the branch ducts 63 are placed near an upper portion of the roof 1002, and typically, the vertical duct 56 runs from the basement to the continuous exhaust duct 54.

With this configuration, solar heated hot water, solar generated electricity and solar heated or cooled air can be provided simultaneously to the property owner. Additionally, a sturdy and reliable roofing structure is provided.

Thus the several aforementioned objects and advantages are most effectively attained. Although preferred embodiments of the invention have been disclosed and described in detail herein, it should be understood that this invention is in no sense limited thereby and its scope is to be determined by that of the appended claims.

What is claimed is:

1. A solar energy system comprising:
photovoltaic panels for generating electricity in response to sunlight;
thermal collector panels for collecting thermal energy from sunlight; and
a heat recovery system including a channel formed from a gap underneath said photovoltaic panels and said thermal collector panels, further including at least one duct for providing air to or retrieving air from said channel, thereby circulating air underneath said photovoltaic cells and said thermal collector panels.

2. The solar energy system of claim 1 wherein said photovoltaic panels and said thermal collector panels are arranged in an array.

3. The solar energy system of claim 2 wherein at least a portion of said thermal collector panels are placed adjacent to each other in said array and at least a portion of said photovoltaic panels are placed adjacent to each other said array.

4. The solar energy system of claim 3 further including a frame for mounting said thermal collector panels and said photovoltaic panels.

5. The solar energy system of claim 4 wherein said frame comprises purlin elements and rafter elements, wherein said purlin elements are generally perpendicular to said rafter elements.

6. The solar energy system of claim 4 wherein said frame is comprised of aluminum.

7. The solar energy system of claim 6 wherein said thermal collector panels and said photovoltaic panels are secured to said frame by structural silicone.

8. The solar energy system of claim 1 wherein said heat recovery system further comprises an exhaust duct and a supply duct.

9. The solar energy system of claim 8 wherein said exhaust duct is located near a top of said array and said supply duct is located near a bottom of said array, wherein air flows between said supply duct and said exhaust duct by said channel.

10. The solar energy system of claim 8 wherein said heat recovery system further includes a return air duct near a bottom of said array.

11. The solar energy system of claim 1 wherein at least a portion of said photovoltaic panels are electrically configured in series with each other.

12. The solar energy system of claim 11 further including an inverter for converting direct current output from said photovoltaic panels into alternating current.

13. The solar energy system of claim 1 wherein said thermal collector panels include a fluid therein for transporting thermal energy.

14. The solar energy system of claim 13 wherein said fluid is anti-freeze fluid.

15. The solar energy system of claim 13 further including pipes between adjacent solar collector panels for circulation of said fluid.

16. The solar energy system of claim 15 wherein said fluid is circulated to a heat exchanger.

17. The solar energy system of claim 16 wherein heat of said fluid is transferred to water in a storage tank.

18. The solar energy system of claim 17 wherein said fluid is free of contact with water in said storage tank.

19. The solar energy system of claim 1 wherein said channel is at least partially lined with rubber.

20. The solar energy system wherein said photovoltaic panels and said thermal collection panels are substantially four feet by four feet in size.
